(19) United States
(12) Patent Application Publication
(10) Pub. No.: US 2026/0324409 A1
(43) Pub. Date: Oct. 15, 2026

(54) INTERCONNECT STRUCTURE INCLUDING SANDWICHED ETCH STOP LAYER AND METHOD FOR MANUFACTURING THE SAME

(71) Applicant: TAIWAN SEMICONDUCTOR MANUFACTURING COMPANY, LTD., Hsinchu (TW)

(72) Inventors: Shu-Wei LI, Hsinchu (TW); Tsu-Chun KUO, Hsinchu (TW); Yu-Chen CHAN, Hsinchu (TW)

(73) Assignee: TAIWAN SEMICONDUCTOR MANUFACTURING COMPANY, LTD., Hsinchu (TW)

(21) Appl. No.: 19/177,052

(22) Filed: Apr. 11, 2025

(51) Int. Cl. H01L 21/768; H01L 23/528

(52) U.S. Cl. CPC H10W 20/46; H10W 20/072; H10W 20/074; H10W 20/435

(57) ABSTRACT

A method for manufacturing an interconnect structure includes: forming a lower interconnect layer over a base structure, the lower interconnect layer including a lower dielectric feature and a lower conductive feature disposed in the lower dielectric feature; forming an etch stop layer on the lower interconnect layer; forming an upper conductive feature on the etch stop layer, a material of the upper conductive feature being different from a material of the etch stop layer; performing a patterning process to form a trench in the upper conductive feature, the etch stop layer having a first portion covered by the upper conductive feature, and a second portion exposed in the trench; and treating the second portion of the etch stop layer so that an electrical resistance of the second portion is greater than an electrical resistance of the first portion of the etch stop layer.

### BACKGROUND

An etch stop layer in an interconnect structure is a thin layer used to control the etching process during semiconductor fabrication. The etch stop layer may prevent over-etching of underlying layers while allowing precise patterning of top layers. This layer ensures that delicate features, like vias and trenches, are not damaged during the fabrication of interconnects, so as to maintain the integrity of the device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIG. 2 is a schematic view illustrating a plurality of levels in a semiconductor structure in accordance with some embodiments.

FIGS. 3 to 15 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain region(s)” may refer to a source or a drain, individually or collectively dependent upon the context.

An etch stop layer is a material layer strategically used in semiconductor fabrication to prevent further etching during etching processes. The etch stop layer acts as a protective barrier, and ensures that only specific areas of a wafer are etched. Typically, materials for the etch stop layer are chosen for their resistances to the etching processes used in semiconductor manufacturing. Reactive ion etching (hereinafter RIE) is a technique that uses both chemically reactive gases and an electric field to etch materials with high precision. During RIE, ions generated from reactive gases are accelerated toward a surface of a wafer, where they react to form volatile byproducts, which are then removed by a vacuum. RIE is widely used in semiconductor fabrication for its ability to etch fine patterns with vertical sidewalls and high anisotropy. When an RIE scheme is used for patterning a dielectric layer on the etch stop layer for forming a trench metal in the dielectric layer, the etch stop layer may include an oxide-based material and/or a nitride-based material, which may cause high contact resistance between the trench metal on the etch stop layer and a via under the etch stop layer. In addition, as transistor and conductive feature pitch scale down, a reduced volume of the trench metal will cause an increase in resistivity of the trench metal to a great extent, especially when the trench metal is made of copper. In addition, the presence of the etch stop layer may result in a relatively high contact resistance between the trench metal and the via, and the high resistivity of the trench metal may cause potential reliability concerns in advanced semiconductor devices. Therefore, the present disclosure is directed toward methods for manufacturing an interconnect structure in which a contact resistance between the trench metal and the via is reduced.

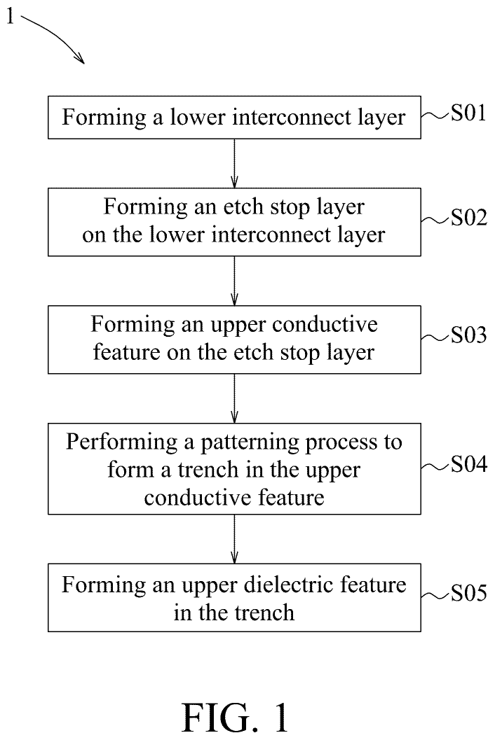

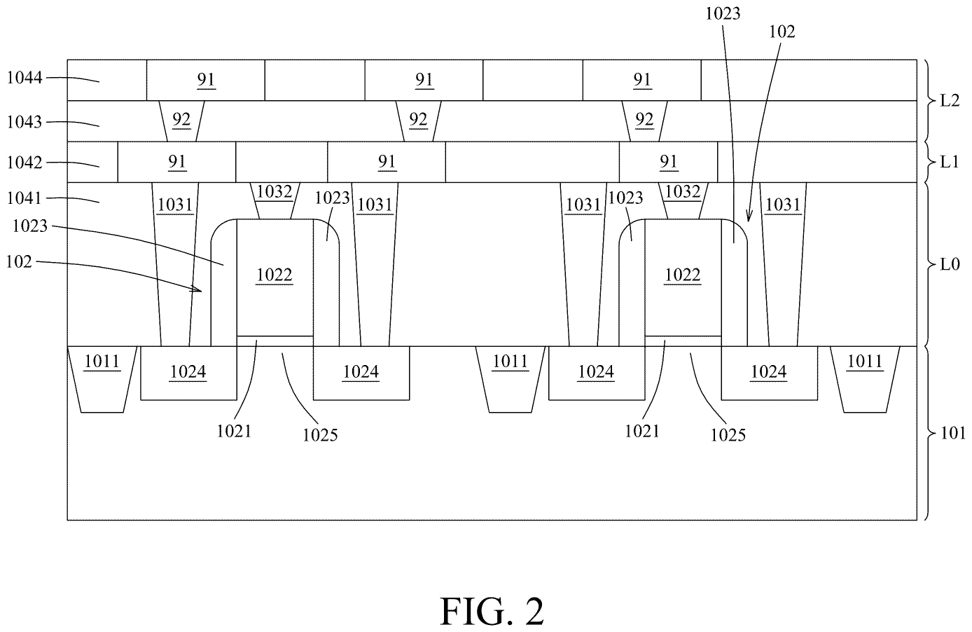

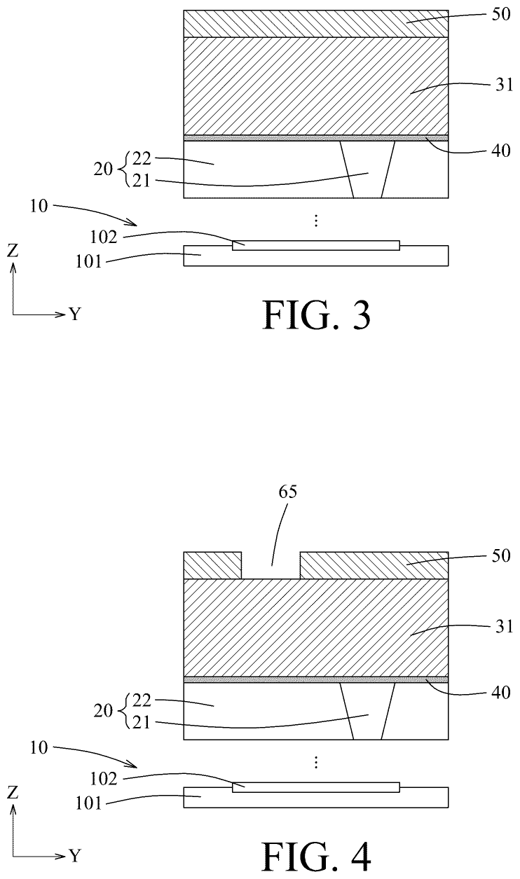

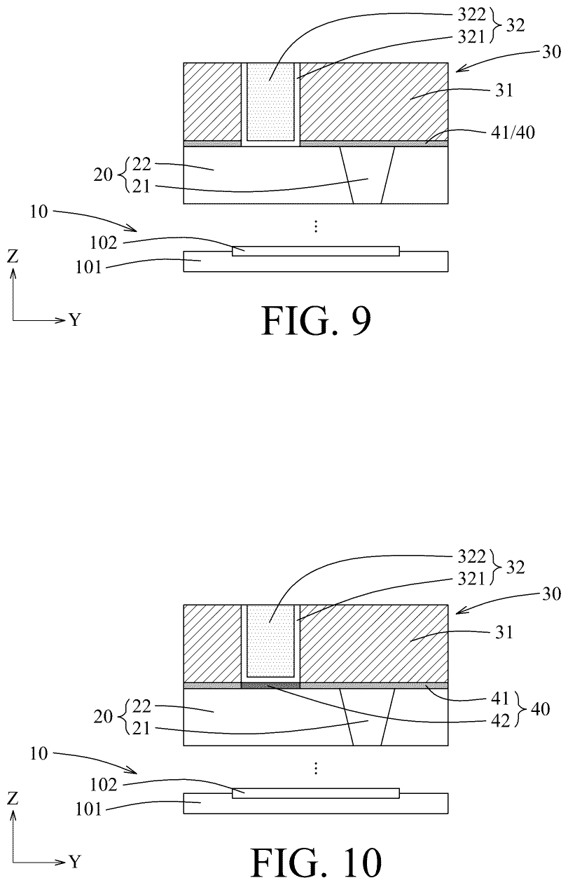

FIG. 1 is a flow diagram illustrating a method for manufacturing an interconnect structure (for example, the interconnect structures shown in FIGS. 9, 10, 14 and 15) in accordance with some embodiments. FIG. 2 is a schematic view of a plurality of levels in a semiconductor structure in accordance with some embodiments, and may not reflect an actual sectional view of the semiconductor structure. FIGS. 3 to 15 illustrate schematic views of intermediate stages of the method in accordance with some embodiments, and the steps illustrated in FIGS. 3 to 15 are also illustrated schematically in the flow diagram shown in FIG. 1. Some repeating structures are omitted in FIGS. 2 to 15 for the sake of brevity. Additional steps can be provided before, after or during the method, and some of the steps described herein may be replaced by other steps or be eliminated.

Referring to FIG. 2, in some embodiments, the semiconductor structure includes a substrate 101, a plurality of semiconductor devices 102 formed on the substrate 101, a plurality of source/drain contacts 1031, a plurality of gate contacts 1032, and a dielectric layer 1041. In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations 1011 to separate each of the semiconductor devices 102 from adjacent ones of the semiconductor devices 102. In some embodiments, the trench isolations 1011 may each be a shallow trench isolation (STI), a deep trench isolation (DTI), or other suitable structures. In some embodiments, the trench isolations 1011 may include silicon oxide, silicon nitride, silicon oxynitride, other low-k (low-dielectric constant) dielectric materials, or combinations thereof. The semiconductor devices 102 may be active devices (for example, transistors, diodes, or the like), passive devices (for example, capacitors, inductors, resistors, or the like), memory devices, decoders, amplifiers, other suitable devices, or combinations thereof. In some embodiments, the semiconductor devices 102 may be transistors. Although the semiconductor devices 102 shown in FIG. 2 are each exemplified as a planar transistor, the semiconductor devices 102 may each be a fin-type field-effect transistor (FinFET), a gate-all-around field-effect transistor (GAAFET), a forksheet field-effect transistor, a complementary field-effect transistor (CFET), other transistors with suitable configurations, or other suitable devices. In some embodiments, each of the transistors 102 may have two source/drain regions 1024 formed in the substrate 101, a channel 1025 located between the two source/drain regions 1024, a gate structure interfacing the channel 1025. The gate structure is formed in the dielectric layer 1041 in a contact-level structure L0, and has a gate dielectric layer 1021 formed over the channel 1025, a gate electrode 1022 formed over the gate dielectric layer 1021, and two spacers 1023 formed respectively at two opposite sides of the gate electrode 1022. The gate dielectric layer 1021 may include or may be made of silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, and so on), other suitable materials, or combinations thereof. The gate electrode 1022 may include or may be made of a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), other suitable materials, or combinations thereof. In some embodiments, the gate electrode 1022 may include or may be made of various n-type or p-type work function metals. Examples of the n-type work function metal include Al, titanium aluminum carbide (TiAlC), TiAl, or other suitable materials. Examples of p-type work function metal include TiN, tungsten nitride (WN), tungsten carbon nitride (WCN), molybdenum nitride (MoN), or other suitable materials. The spacers 1023 may include or may be made of a nitride-based material, such as silicon nitride, silicon oxynitride, silicon carbon nitride, silicon oxycarbonnitride, other suitable materials, or combinations thereof. The semiconductor devices 102 may be electrically connected to external circuits through the source/drain contacts 1031 and the gate contacts 1032 formed in the dielectric layer 1041. In some embodiments, the dielectric layer 1041 includes or is made of a low-k dielectric material. In some embodiments, the dielectric layer 1041 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1041 are within the contemplated scope of the present disclosure. In some embodiments, each of the source/drain contacts 1031 and the gate contacts 1032 includes or is made of Cu, Co, Ru, Mo, Cr, W, Mn, Rh, Ir, Ni, Pd, Ag, Au, Al, alloys thereof, graphene, other suitable conductive materials, or combinations thereof. In some embodiments, each of the source/drain contacts 1031 and the gate contacts 1032 may be formed by a single damascene process involving physical vapor deposition (hereinafter PVD), chemical vapor deposition (hereinafter CVD), atomic layer deposition (hereinafter ALD) or other suitable processes. In some embodiments, the semiconductor structure further includes one or multiple interconnect-level structures L1, L2, L3, . . . Ln (L3 to Ln are not shown). In the interconnect-level structure L1, metal lines 91 are formed in a dielectric layer 1042. In each of the interconnect-level structures L2 to Ln, metal vias 92 are formed in a dielectric layer 1043, and metal lines 91 are formed in a dielectric layer 1044. Suitable materials for the metal lines 91 and metal vias 92 are similar to those for the source/drain contacts 1031 and the gate contacts 1032. Suitable materials for the dielectric layers 1042, 1043, 1044 are similar to those for the dielectric layer 1041.

Referring to FIG. 3, a base structure 10 is shown. The base structure 10 includes the substrate 101, and the semiconductor devices 102 (one of which is shown). A lower interconnect layer 20 is formed over the base structure 10. The lower interconnect layer 20 includes a lower dielectric feature 22 and a lower conductive feature 21 disposed in the lower dielectric feature 22. In some embodiments, the lower conductive feature 21 may be one of the source/drain contacts 1031 and the gate contacts 1032 located in the contact-level structure L0 shown in FIG. 2. In some other embodiments, the lower conductive feature 21 may be one of the metal lines 91 located in one of the interconnect-level structures L1 to Ln (only L1 and L2 are shown in FIG. 2). In certain embodiments, the lower conductive feature 21 may be one of the metal vias 92 located in one of the interconnect-level structures L2 to Ln (only L2 is shown in FIG. 2). The lower dielectric feature 22 shown in FIG. 3 may be one of the dielectric layers 1041 to 1044 shown in FIG. 2. In the following descriptions, the lower conductive feature 21 is exemplified to include a metal via. In some embodiments, the lower conductive feature 21 may include or be made of Cu, Co, Ru, Mo, Cr, W, Mn, Rh, Ir, Ni, Pd, Ag, Au, Al, alloys thereof, other suitable materials, or combinations thereof. In some embodiments, the lower conductive feature 21 is formed in the lower dielectric feature 22 using a single damascene process involving PVD, CVD, ALD or other suitable processes. Thereafter, an etch stop layer 40 is formed on the lower interconnect layer 20. A material of the etch stop layer 40 is different from the material of the lower conductive feature 21. In some embodiments, the etch stop layer 40 may include or be made of titanium, tantalum, alloys thereof, other suitable materials, or combinations thereof. In some embodiments, the etch stop layer 40 may be formed using a suitable deposition process such as CVD, plasma-enhanced CVD (hereinafter PECVD), ALD, a thermal ALD process, or other suitable processes. Other materials, configurations, and/or processes suitable for forming the etch stop layer 40 are also within the contemplated scope of the present disclosure. Afterwards, an upper conductive feature 31 is formed on the etch stop layer 40. In some embodiments, the upper conductive feature 31 is thicker than the lower conductive feature 21, and a material of the upper conductive feature 31 is different from the material of the etch stop layer 40. In some embodiments, the upper conductive feature 31 may include or be made of ruthenium, tungsten, molybdenum, copper, cobalt, nickel, aluminum, hafnium, zirconium, yttrium, chromium, manganese, rhodium, iridium, palladium, silver, aurum, alloys thereof, graphene, intercalated graphene, N-doped graphene, O-doped graphene, modified graphene, hexagonal boron nitride (h-BN), intercalated h-BN, N-doped h-BN, O-doped h-BN, modified h-BN, transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, a carbon nanowire, a carbon nanotube, a carbon nanorod, 1D metal, intercalated 1D metal, N-doped 1D metal, O-doped 1D metal, modified 1D metal, 1D alloy, intercalated 1D alloy, N-doped 1D alloy, O-doped 1D alloy, modified 1D alloy, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, other suitable materials, or combinations thereof. The TMD includes a transition metal (e.g., Zr, Ta, Nb, Hf, W, Mo, Ga, Sn, etc.,) and a chalcogenide (Se, S, Te, etc.). In some embodiments, the TMD includes MoS₂, TaS₂, HfS₂, WSe₂, or combinations thereof. In some embodiments, the upper conductive feature 31 may be formed using a suitable deposition process such as PVD, CVD, PECVD, ALD, plasma-enhanced ALD (hereinafter PEALD), electrochemical plating (hereinafter ECP), electroless chemical deposition (hereinafter ELD), or other suitable processes. Other materials, configurations, and/or processes suitable for forming the upper conductive feature 31 are also within the contemplated scope of the present disclosure. Then, a mask 50 is formed on the upper conductive feature 31. In some embodiments, the mask 50 is a mask layer for patterning, is formed over the upper conductive feature 31 by, for example, spin coating, deposition processes, or other suitable processes, and includes or is made of a material different from the material of the upper conductive feature 31. In some embodiments, the mask 50 may be a photoresist layer. In some embodiments, the mask 50 may be formed by depositing a hard mask layer on the upper conductive feature 31 opposite to the base structure 10, and the hard mask layer may include or be made of tungsten carbide, silicon oxide, other suitable materials, or combinations thereof.

Referring to FIG. 4, an opening 65 is formed in the mask 50 so that a portion of the upper conductive feature 31 is exposed in the opening 65. The opening 65 is offset from the lower conductive feature 21 in a Y direction. In some embodiments, when the mask 50 is the photoresist layer, the mask 50 may be patterned using a photolithography process. In some other embodiments, when the mask 50 is the hard mask layer, a photolithography process and a subsequent etching process may be used. The photolithography process may include: forming a photoresist layer over a structure to be patterned by, for example, spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In other words, when the mask 50 is the photoresist layer, the etching process is omitted; and when the mask 50 is the hard mask layer, the photolithography process and the etching process are used. In the following description, a photolithography process or an etching process, unless otherwise stated or defined in this disclosure, may be performed in a way similar to the above-mentioned ones. Other suitable materials and processes for forming the mask 50 and the opening 65 are within the contemplated scope of the present disclosure.

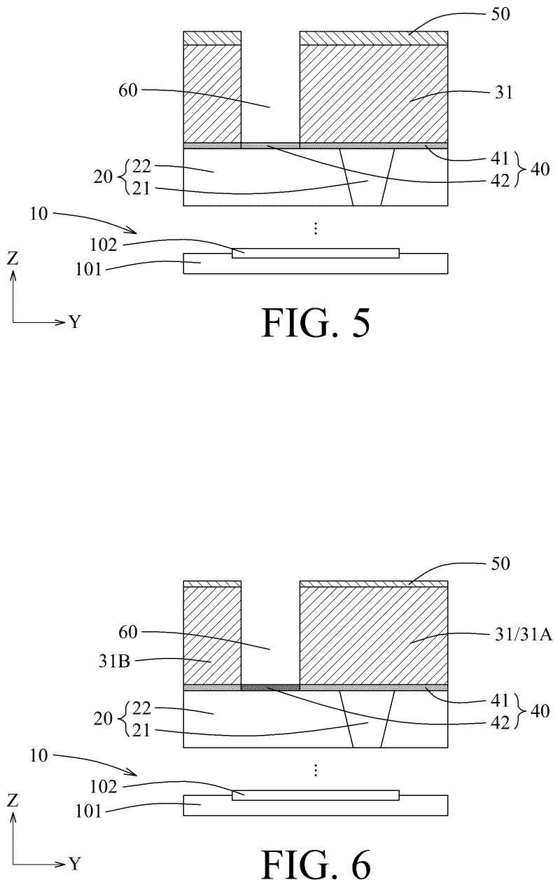

Referring to FIG. 5, after the opening 65 is formed, a patterning process is performed to remove the portion of the upper conductive feature 31 that is exposed in the opening 65 so that a trench 60 is formed in the upper conductive feature 31. The patterning process may be performed using a suitable etching process, such as reactive-ion etching (hereinafter RIE), dry etching, other suitable processes, or combinations thereof, so as to obtain a structure as illustrated in FIG. 5. The trench 60 is offset from the lower conductive feature 21. Referring to FIGS. 4 and 5, in some embodiments, during the removal process, a thickness of the mask 50 in a Z direction that is different from (e.g., perpendicular to) the Y direction may be reduced. At this time, the etch stop layer 40 has a first portion 41 covered by the upper conductive feature 31 (i.e., the first portion 41 is disposed between the upper conductive feature 31 and the lower conductive feature 21), and a second portion 42 exposed in the trench 60. Each of the first portion 41 and the second portion 42 of the etch stop layer 40 may include or be made of titanium, tantalum, alloys thereof, other suitable materials, or combinations thereof (i.e., the first portion 41 and the second portion 42 of the etch stop layer 40 have or are made of a same material that is a metal material). In some embodiments, a concentration of non-metal elements in the second portion 42 is the same as a concentration of the non-metal elements in the first portion 41. The non-metal elements may include or be made of oxygen elements, nitrogen elements, a combination thereof, or other suitable non-metal elements.

Referring to FIG. 6, after the second portion 42 of the etch stop layer 40 is exposed in the trench 60, the second portion 42 is treated in a treating process so that an electrical resistance of the second portion 42 is greater than an electrical resistance of the first portion 41 of the etch stop layer 40. In some embodiments, the second portion 42 may be treated in the patterning process. In some other embodiments, the second portion 42 may be treated by an additional dry etching process or other suitable processes. For example, in some embodiments, the second portion 42 may be treated by gases that are generated during the dry etching process which is performed to form the trench 60 (i.e., the second portion 42 is exposed to the gases). In some other embodiments, the second portion 42 may be treated by ambient air or gas when the trench 60 is formed. In treating the second portion 42, the non-metal elements (i.e., oxygen elements, nitrogen elements, a combination thereof, or other suitable non-metal elements) in the gases and/or the air are diffused into the metal material in the second portion 42. Thus, a treating process may or may not be a part of the patterning process. In some embodiments, the second portion 42 is treated to include titanium oxide, titanium nitride, tantalum oxide, tantalum nitride, or combinations thereof. Referring to FIGS. 5 and 6, in some embodiments, during the treating process, the thickness of the mask 50 in the Z direction may be reduced. After treating the second portion 42, a concentration of the non-metal elements in the second portion 42 is greater than a concentration of the non-metal elements in the first portion 41. In some embodiments, a concentration of the non-metal elements in a lower part of the second portion 42 that is proximate to the lower interconnect layer 20 is no greater than a concentration of the non-metal elements in an upper part of the second portion 42 that is distal from the lower interconnect layer 20. For example, the concentration of the non-metal elements in the second portion 42 may be gradually reduced toward the lower interconnect layer 20, or may be consistent from the trench 60 to the lower interconnect layer 20 as long as the concentration of the non-metal elements in the second portion 42 is greater than the concentration of the non-metal elements in the first portion 41. The treated second portion 42 may protect the lower dielectric feature 22 so that the lower dielectric feature 22 may not be etched. In some embodiments, after the treating process, the second portion 42 is made of metal oxide or metal nitride, while the first portion 41 is made of metal. In such case, even if the second portion 42 is not removed in a subsequent process, remaining portions 31A, 31B of the upper conductive feature 31 are less likely to be undesirably electrically connected through the second portion 42 of the etch stop layer 40.

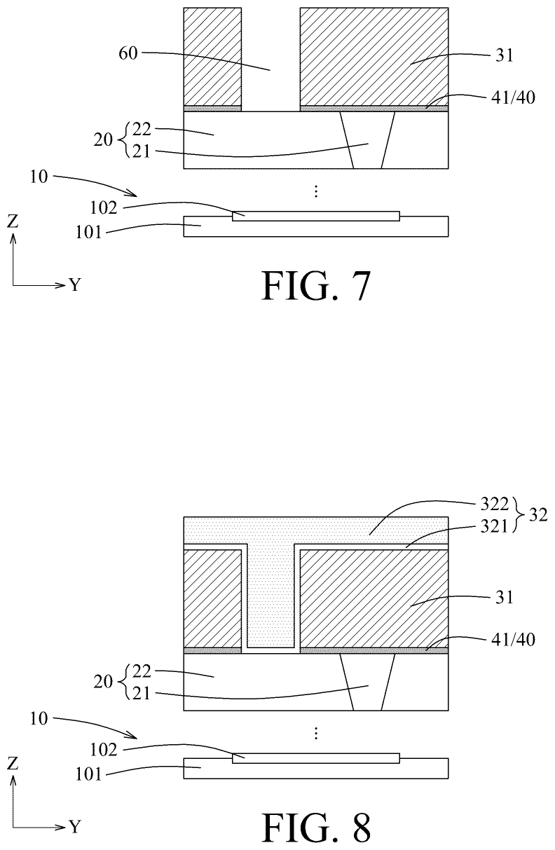

Referring to FIG. 7, after treating the second portion 42 (see FIG. 6) of the etch stop layer 40, the second portion 42 is removed. As such, the trench 60 is enlarged and the lower dielectric feature 22 is exposed in the trench 60. In some embodiments, the treated second portion 42 (see FIG. 6) may be removed by a suitable etching process, such as wet etching, dry etching, other suitable processes, or combinations thereof, so as to obtain a structure as illustrated in FIG. 7. It is noted that the etching process for removing the treated second portion 42 (see FIG. 6) has to be different from the etching process for removing the portion of the upper conductive feature 31 through the mask 50 (see FIGS. 4 and 5). For example, if the portion of the upper conductive feature 31 is removed by a dry etching process, the treated second portion 42 is removed by an etching process other than the dry etching process. Referring to FIGS. 6 and 7, in some embodiments, while removing the treated second portion 42 (see FIG. 6), the mask 50 (see FIG. 6) is removed simultaneously.

Referring to FIG. 8, after removing the treated second portion 42 (see FIG. 6), an upper dielectric feature 32 is formed in the trench 60 (see FIG. 7). The upper dielectric feature 32 includes a barrier layer 321 and an inner dielectric layer 322. The barrier layer 321 is formed over the upper conductive feature 31 to cover the lower dielectric feature 22. The barrier layer 321 may be formed using, for example, CVD, ALD or other suitable processes. In some embodiments, the barrier layer 321 may include or be made of aluminum nitride (AlN), aluminum oxide (AlO), silicon oxide (SiO), silicon oxycarbide (SiOC), silicon oxycarbonitride (SiOCN), other suitable materials, or combinations thereof. In some embodiments, the barrier layer 321 is in contact with the first portion 41 of the etch stop layer 40, and an electrical conductivity of the first portion 41 is greater than an electrical conductivity of the barrier layer 321. In some embodiments, the barrier layer 321 is made of a dielectric material for preventing diffusion of metal elements in the upper conductive feature 31 into the inner dielectric layer 322. Afterwards, the inner dielectric layer 322 is formed over the barrier layer 321 to fill the trench 60 (see FIG. 7). The inner dielectric layer 322 may be formed by depositing a dielectric material of the inner dielectric layer 322 using a suitable deposition process such as PVD, CVD, ALD, PECVD, PEALD, a spin-coating process, or other suitable processes. In some embodiments, the inner dielectric layer 322 may include or be made of silicon oxide, silicon oxycarbide, silicon oxycarbonitride, or combinations thereof, and has a dielectric constant ranging from about 1.5 to about 3.9, but other ranges of values are also within the contemplated scope of the present disclosure. A dielectric constant of the barrier layer 321 is greater than the dielectric constant of the dielectric layer 322. The inner dielectric layer 322 is separated from the upper conductive feature 31 by the barrier layer 321.

Referring to FIG. 9, a planarization process (e.g., a chemical mechanical polishing process (CMP)) is performed on the upper dielectric feature 32 to expose the upper conductive feature 31. After the planarization process, an upper interconnect layer 30 is formed and includes the planarized upper conductive feature 31 and the planarized upper dielectric feature 32. At this time, the upper interconnect layer 30 has a planarized upper surface, the etch stop layer 40 is located and sandwiched between the lower interconnect layer 20 and the upper interconnect layer 30, and a thickness of the planarized upper conductive feature 31 is still greater than the thickness of the lower conductive feature 21. In some embodiments, the lower conductive feature 21 is exemplified as a metal via and the planarized upper conductive feature 31 is exemplified as a trench metal.

In some embodiments, some steps in the method may be modified, replaced, or eliminated without departure from the spirit and scope of the present disclosure. In some alternative embodiments, the interconnecting structure may further include additional features, and/or some features present in the interconnect structure may be modified, replaced, or eliminated without departure from the spirit and scope of the present disclosure. The method illustrated by FIG. 1 may be applied for forming another interconnect structure in which the materials used therein and/or the aspect ratio and/or the pitch of the conductive lines/vias are different from those illustrated in step S01 to S05. The method illustrated by FIG. 1 may further be applied for a semiconductor manufacturing process that uses 20 nanometer technology, or technology involving a dimension greater/smaller than 20 nanometers. Furthermore, other techniques suitable for forming the interconnect structure that has an etch stop layer, which has a lower electrical resistance and which is disposed between two conductive features may be integrated into the method of this disclosure.

Referring to FIGS. 4 and 7 again, in some embodiments, when the patterning process for patterning the upper conductive feature 31 is well-controlled, the second portion 42 shown in FIG. 5 may be removed without being treated. In such case, the lower dielectric feature 22 may still be prevented from being etched. Thus, the untreated second portion 42 of the etch stop layer 40 may be removed in the patterning process for patterning the upper conductive feature 31, so as to obtain a structure as illustrated in FIG. 7 for subsequent processes illustrated in FIGS. 8 and 9.

FIG. 10 is a schematic view subsequent to FIG. 6, and illustrates a possible intermediate stage of the method depicted in FIG. 1 in accordance with some embodiments. Referring to FIG. 10, after the second portion 42 of the etch stop layer 40 is treated (see also FIG. 6), the mask 50 is removed while the second portion 42 is not removed. Then, the barrier layer 321 and the inner dielectric layer 322 are formed in a manner similar to that described with reference to FIGS. 8 and 9, so as to obtain a structure as illustrated in FIG. 10. In some embodiments, the second portion 42 is disposed between the upper dielectric feature 32 and the lower dielectric feature 22, and the inner dielectric layer 322 is separated from the upper conductive feature 31 and the second portion 42 by the barrier layer 321.

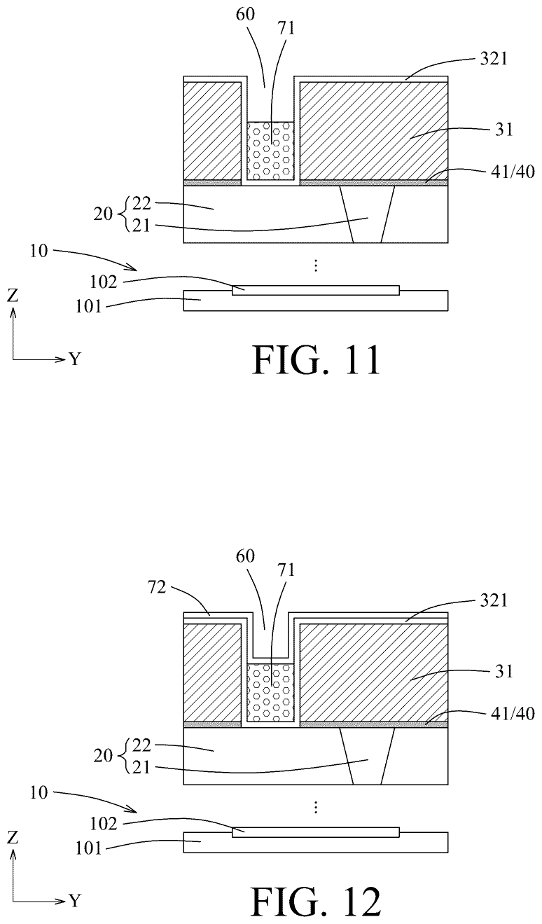

FIGS. 11 to 14 are schematic views subsequent to FIG. 7, and illustrate possible intermediate stages of the method depicted in FIG. 1 in accordance with some embodiments.

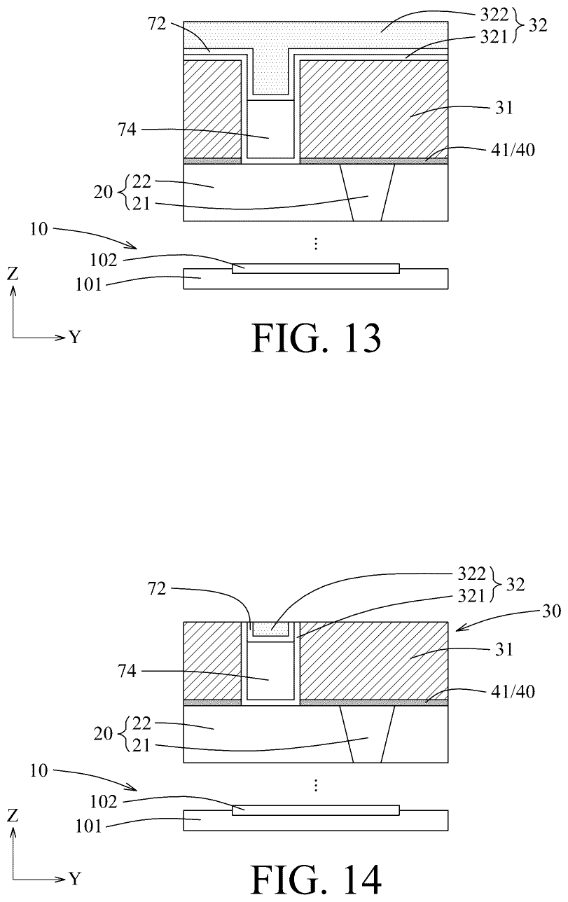

Referring to FIG. 11, after the treated second portion 42 is removed (see FIGS. 6 and 7), the barrier layer 321 is formed over the upper conductive feature 31 and in the trench 60 (see FIG. 7) to cover the lower dielectric feature 22. Suitable materials and processes for forming the barrier layer 321 are similar to those for forming the barrier layer 321 described with reference to FIG. 8, and thus details thereof are omitted for the sake of brevity. Then, a sacrificial layer 71 is formed over the barrier layer 321 in the trench 60. In some embodiments, the sacrificial layer 71 may be an organic layer including C, O, N, and H. In some embodiments, the sacrificial layer 71 may include or be made of polyurea, polylactic acid, polycaprolactone, poly(ethylene oxide), polyacrylate, polyvinyl alcohol, other suitable materials, or combinations thereof, but is not limited thereto. In some embodiments, the sacrificial layer 71 may be formed over the barrier layer 321 to fill the trench 60 by CVD, ALD, molecular layer deposition (hereinafter MLD), a spin-on process, or combinations thereof, and a thickness of the sacrificial layer 71 in the Z direction may be tuned by a thermal recess process, an etching back process (such as dry etching, wet etching or a combination thereof), or other suitable processes. Afterwards, the sacrificial layer 71 is recessed so as to obtain a structure as illustrated in FIG. 11 in which the trench 60 is partially unfilled. In some embodiments, the sacrificial layer 71 may be recessed by a thermal baking process, an ultraviolet (hereinafter UV) curing process, both the thermal baking process and the UV curing process, or other suitable processes. In some embodiments, the recessed sacrificial layer 71 has a thickness ranging from about 10 Å to about 490 Å, but other ranges of values are also within the contemplated scope of the present disclosure. In some embodiments, an upper surface of the recessed sacrificial layer 71 is at a level lower than a level of an upper surface of the upper conductive feature 31. If the recessed sacrificial layer 71 is thinner than about 10 Å, an air gap 74 (see FIG. 13) to be formed hereafter may have a relatively low volume, and thus the effectiveness of reducing parasitic capacitance may be insufficient. If the recessed sacrificial layer 71 is thicker than about 490 Å, the structure of the air gap 74 to be formed may be unstable.

Referring to FIG. 12, a sustaining layer 72 is formed over the barrier layer 321 and the recessed sacrificial layer 71. In some embodiments, the sustaining layer 72 may include or be made of porous silicon oxide, silicon oxycarbide, silicon oxynitride, silicon carbonitride, silicon carbon oxynitride, other suitable materials, or combinations thereof, and has a thickness ranging from about 2 Å to about 100 Å, but other ranges of values are also within the contemplated scope of the present disclosure. In some embodiments, the sustaining layer 72 may be formed by PVD, CVD, ALD, PECVD, PEALD, or other suitable processes, and may provide good mechanical strength to maintain robustness of an air-gap structure. In some embodiments, because the upper surface of the recessed sacrificial layer 71 is at a level lower than a level of the upper surface of the upper conductive feature 31, after the sustaining layer 72 is formed over the barrier layer 321 and the recessed sacrificial layer 71, the trench 60 is still partially unfilled.

Referring to FIG. 13, the recessed sacrificial layer 71 (see FIG. 12) is removed to form an air gap 74 between the sustaining layer 72 and the barrier layer 321. In some embodiments, the recessed sacrificial layer 71 may be removed by a thermal baking process, a UV curing process, both the thermal baking process and the UV curing process, or other suitable processes so as to permit the recessed sacrificial layer 71 to be decomposed, vaporized, and degassed through the inner dielectric layer 322 and the sustaining layer 72. In some embodiments, the sustaining layer 72 may collapse after removal of the recessed sacrificial layer 71 when the sustaining layer 72 is too thin (e.g., thinner than about 2 Å), and the recessed sacrificial layer 71 may not be removed easily when the sustaining layer 72 is too thick (e.g., thicker than about 100 Å). In some embodiments, decomposition of the recessed sacrificial layer 71 is executed at a temperature ranging from about 250 °C to about 350 °C. Process parameters (for example, but not limited to, temperature, time period, etc.) for decomposition of the recessed sacrificial layer 71 may be adjusted according to the selection of polymers for forming the recessed sacrificial layer 71 and in consideration of thermal budget of the structure shown in FIG. 13 such that less residue of the recessed sacrificial layer 71 remains in the structure. After forming the air gap 74, the inner dielectric layer 322 is formed over the sustaining layer 72 t o fill the trench 60 (see FIG. 12). Suitable materials and processes for forming the inner dielectric layer 322 are similar to those for forming the inner dielectric layer 322 described with reference to FIG. 8, and thus details thereof are omitted for the sake of brevity. The inner dielectric layer 322 is separated from the barrier layer 321 by the sustaining layer 72. After the inner dielectric layer 322 is formed, the upper dielectric feature 32 is obtained, and the air gap 74 is located between the inner dielectric layer 322 and the barrier layer 321.

Referring to FIG. 14, a planarization process (e.g., a CMP process) is performed on the upper dielectric feature 32 to expose the upper conductive feature 31. After the planarization process, the upper interconnect layer 30 is formed and includes the upper conductive feature 31, the upper dielectric feature 32, the sustaining layer 72, and the air gap 74. At this time, each of the sustaining layer 72, the barrier layer 321, and the lower conductive feature 31 is exposed from the inner dielectric layer 322, the upper interconnect layer 30 has a planarized upper surface, the etch stop layer 40 is located between the lower interconnect layer 20 and the upper interconnect layer 30, and a thickness of the planarized upper conductive feature 31 is still greater than the thickness of the lower conductive feature 21.

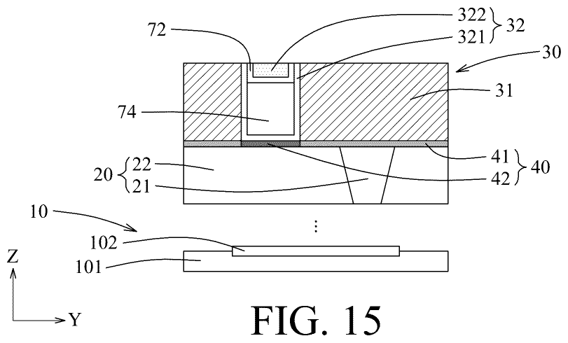

FIG. 15 is a schematic view subsequent to FIG. 6, and illustrates a possible intermediate stage of the method depicted in FIG. 1 in accordance with some embodiments. Referring to FIG. 15, after the second portion 42 of the etch stop layer 40 is treated (see also FIG. 6), the mask 50 is removed while the second portion 42 is not removed. Then, the barrier layer 321, the recessed sacrificial layer 71, the sustaining layer 72, the air gap 74 and the inner dielectric layer 322 are formed in a manner similar to that described with reference to FIGS. 11 to 14, so as to obtain the structure as illustrated in FIG. 15. At this time, the upper interconnect layer 30 is formed and includes the upper conductive feature 31, the upper dielectric feature 32, the sustaining layer 72, and the air gap 74. In addition, each of the sustaining layer 72, the barrier layer 321, and the lower conductive feature 31 is exposed from the inner dielectric layer 322, the upper interconnect layer 30 has a planarized upper surface, the etch stop layer 40 is located between the lower interconnect layer 20 and the upper interconnect layer 30, and a thickness of the planarized upper conductive feature 31 is still greater than the thickness of the lower conductive feature 21. In some embodiments, the second portion 42 is disposed between the upper dielectric feature 32 and the lower dielectric feature 22, and the inner dielectric layer 322, the sustaining layer 72 and the air gap 74 are separated from the upper conductive feature 31 and the second portion 42 by the barrier layer 321. In some embodiments, the air gap 74 is located over the second portion 42 and is offset from the lower conductive feature 21.

Steps S01 to S03 in the flow diagram shown in FIG. 1 are exemplified by the structure shown in FIG. 3. Step S04 in the flow diagram shown in FIG. 1 is exemplified by the structures shown in FIGS. 4 to 7. Step S05 in the flow diagram shown in FIG. 1 is exemplified by the structures shown in FIGS. 8 and 9. FIG. 10 illustrates another possible interconnect structure obtained in steps S04 and S05 in accordance with some embodiments. FIGS. 11 to 14 illustrate some possible intermediate stages of step S05 in accordance with some embodiments. FIG. 15 illustrates still another possible interconnect structure obtained in steps S04 and S05 in accordance with some embodiments.

In summary, by virtue of the etch stop layer 40 (see FIGS. 5 and 6) including a metal material, and by virtue of the etch stop layer 40 being able to be transformed when being treated, the etch stop layer 40 may have two different functions. Firstly, the second portion 42 of the etch stop layer 40 can function to protect the lower dielectric feature 22 (see FIGS. 5 and 6) from being undesirably etched or damaged. Secondly, the first portion 41 of the etch stop layer 40, which is disposed between the lower conductive feature 21 and the upper conductive feature 31 (see FIGS. 5 and 6) can function as a conductive layer. Therefore, during RIE, a contact resistance between a trench metal (e.g., the upper conductive feature 31) on the etch stop layer 40 and a via (e.g., the lower conductive feature 21) under the etch stop layer 40 may be greatly reduced. Moreover, since the second portion 42 of the etch stop layer 40 can well protect the lower dielectric feature 22, a superficial profile of the lower dielectric feature 22 (e.g., an upper surface of the lower dielectric feature 22 that is in contact with the etch stop layer 40) may be maintained as undamaged. In addition, by virtue of the air gap 74 (see FIGS. 14 and 15) formed between the barrier layer 321 and the inner dielectric layer 322, a parasitic capacitance of the interconnect structure is reduced.

In accordance with some embodiments of the present disclosure, a method for manufacturing an interconnect structure includes: forming a lower interconnect layer over a base structure, the lower interconnect layer including a lower dielectric feature and a lower conductive feature disposed in the lower dielectric feature; forming an etch stop layer on the lower interconnect layer; forming an upper conductive feature on the etch stop layer, the upper conductive feature being thicker than the lower conductive feature, a material of the upper conductive feature being different from a material of the etch stop layer; performing a patterning process to form a trench in the upper conductive feature, the trench being offset from the lower conductive feature, the etch stop layer having a first portion covered by the upper conductive feature, and a second portion exposed in the trench; treating the second portion of the etch stop layer so that an electrical resistance of the second portion is greater than an electrical resistance of the first portion of the etch stop layer; and after treating the second portion of the etch stop layer, forming an upper dielectric feature in the trench.

In accordance with some embodiments of the present disclosure, the upper conductive feature includes ruthenium, tungsten, molybdenum, copper, cobalt, nickel, aluminum, hafnium, zirconium, yttrium, chromium, manganese, rhodium, iridium, palladium, silver, aurum, alloys thereof, or combinations thereof.

In accordance with some embodiments of the present disclosure, the upper conductive feature includes graphene, intercalated graphene, N-doped graphene, O-doped graphene, modified graphene, hexagonal boron nitride (h-BN), intercalated h-BN, N-doped h-BN, O-doped h-BN, modified h-BN, transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, a carbon nanowire, a carbon nanotube, a carbon nanorod, 1D metal, intercalated 1D metal, N-doped 1D metal, O-doped 1D metal, modified 1D metal, 1D alloy, intercalated 1D alloy, N-doped 1D alloy, O-doped 1D alloy, modified 1D alloy, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, or combinations thereof.

In accordance with some embodiments of the present disclosure, the second portion of the etch stop layer is treated in the patterning process.

In accordance with some embodiments of the present disclosure, the second portion of the etch stop layer is treated by a dry etching process.

In accordance with some embodiments of the present disclosure, each of the first portion and the second portion of the etch stop layer includes a metal material; before treating the second portion of the etch stop layer, a concentration of non-metal elements in the second portion is same as a concentration of the non-metal elements in the first portion; and after treating the second portion of the etch stop layer, a concentration of the non-metal elements in the second portion is greater than a concentration of the non-metal elements in the first portion.

In accordance with some embodiments of the present disclosure, the metal material includes titanium, tantalum, or a combination thereof, and the non-metal elements include oxygen elements, nitrogen elements, or a combination thereof.

In accordance with some embodiments of the present disclosure, before treating the second portion of the etch stop layer, the first portion and the second portion of the etch stop layer have a same material that is a metal material; and in treating the second portion of the etch stop layer, non-metal elements are diffused into the metal material in the second portion.

In accordance with some embodiments of the present disclosure, a concentration of the non-metal elements in a lower part of the second portion of the etch stop layer that is proximate to the lower interconnect layer is no greater than a concentration of the non-metal elements in an upper part of the second portion that is distal from the lower interconnect layer.

In accordance with some embodiments of the present disclosure, the upper dielectric feature includes a barrier layer and an inner dielectric layer that is separated from the upper conductive feature by the barrier layer.

In accordance with some embodiments of the present disclosure, the barrier layer includes aluminum nitride, aluminum oxide, silicon oxide, silicon oxycarbide, silicon oxycarbonitride, or combinations thereof.

In accordance with some embodiments of the present disclosure, the dielectric layer includes silicon oxide, silicon oxycarbide, silicon oxycarbonitride, or combinations thereof, and has a dielectric constant ranging from 1.5 to 3.9.

In accordance with some embodiments of the present disclosure, a dielectric constant of the barrier layer is greater than a dielectric constant of the inner dielectric layer.

In accordance with some embodiments of the present disclosure, an electrical conductivity of the first portion of the etch stop layer is greater than an electrical conductivity of the barrier layer.

In accordance with some embodiments of the present disclosure, the upper dielectric feature is formed with an air gap located between the barrier layer and the inner dielectric layer.

In accordance with some embodiments of the present disclosure, after treating the second portion of the etch stop layer, the second portion is removed; and after removing the second portion, the upper dielectric feature is formed in the trench.

In accordance with some embodiments of the present disclosure, a method for manufacturing an interconnect structure includes: forming a lower interconnect layer over a base structure that is formed with at least one transistor, the lower interconnect layer including a lower conductive feature and a lower dielectric feature, the lower conductive feature being made of a first conductive material; forming an etch stop layer on the lower interconnect layer, the etch stop layer being made of a metal material different from the first conductive material; forming an upper conductive feature on the etch stop layer, the upper conductive feature being thicker than the lower conductive feature, the upper conductive feature being made of a second conductive material different from the metal material; performing a patterning process to pattern the upper conductive feature and the etch stop layer so as to form a trench; and forming an upper dielectric feature in the trench.

In accordance with some embodiments of the present disclosure, the etch stop layer includes titanium, tantalum, alloys thereof, or combinations thereof.

In accordance with some embodiments of the present disclosure, the upper dielectric feature includes a barrier layer and an inner dielectric layer that is separated from the upper conductive feature by the barrier layer, an electrical conductivity of the etch stop layer is greater than an electrical conductivity of the barrier layer.

In accordance with some embodiments of the present disclosure, an interconnect structure includes: a lower interconnect layer formed over a base structure including at least one transistor, the lower interconnect layer including a lower dielectric feature and a lower conductive feature; an upper interconnect layer formed on the lower interconnect layer opposite to the base structure, the upper interconnect layer including an upper conductive feature and an upper dielectric feature, a thickness of the upper conductive feature being greater than a thickness of the lower conductive feature; and an etch stop layer disposed between the lower interconnect layer and the upper interconnect layer, and having a first portion and a second portion, the first portion being disposed between the upper conductive feature and the lower conductive feature, the second portion being disposed between the upper dielectric feature and the lower dielectric feature, an electrical resistance of the first portion being less than an electrical resistance of the second portion.

In accordance with some embodiments of the present disclosure, a method for manufacturing an interconnect structure includes: forming a lower interconnect layer over a base structure that is formed with at least one transistor, the lower interconnect layer including a lower conductive feature and a lower dielectric feature; forming an etch stop layer on the lower interconnect layer, the etch stop layer being made of a metal material; forming an upper conductive feature on the etch stop layer, the upper conductive feature being thicker than the lower conductive feature; performing a patterning process to pattern the upper conductive feature so that the upper conductive feature is formed with a trench, and the etch stop layer has a first portion covered by the upper conductive feature, and a second portion exposed in the trench; treating the second portion of the etch stop layer so that the second portion includes non-metal elements; and after treating the second portion of the etch stop layer, forming an upper dielectric feature in the trench.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a lower interconnect layer over a base structure, the lower interconnect layer including a lower dielectric feature and a lower conductive feature disposed in the lower dielectric feature;
forming an etch stop layer on the lower interconnect layer;
forming an upper conductive feature on the etch stop layer, the upper conductive feature being thicker than the lower conductive feature, a material of the upper conductive feature being different from a material of the etch stop layer;
performing a patterning process to form a trench in the upper conductive feature, the trench being offset from the lower conductive feature, the etch stop layer having a first portion covered by the upper conductive feature, and a second portion exposed in the trench;
treating the second portion of the etch stop layer so that an electrical resistance of the second portion is greater than an electrical resistance of the first portion of the etch stop layer; and
after treating the second portion of the etch stop layer, forming an upper dielectric feature in the trench.

2. The method of claim 1, wherein the upper conductive feature includes ruthenium, tungsten, molybdenum, copper, cobalt, nickel, aluminum, hafnium, zirconium, yttrium, chromium, manganese, rhodium, iridium, palladium, silver, aurum, alloys thereof, or combinations thereof.

3. The method of claim 1, wherein the upper conductive feature includes graphene, intercalated graphene, N-doped graphene, O-doped graphene, modified graphene, hexagonal boron nitride (h-BN), intercalated h-BN, N-doped h-BN, O-doped h-BN, modified h-BN, transition-metal dichalcogenide (TMD), intercalated TMD, N-doped TMD, O-doped TMD, modified TMD, germanane, intercalated germanane, N-doped germanane, O-doped germanane, modified germanane, Ni₃(2,3,6,7,10,11-hexaiminotriphenylene)₂ (Ni₃(HITP)₂), intercalated Ni₃(HITP)₂, N-doped Ni₃(HITP)₂, O-doped Ni₃(HITP)₂, modified Ni₃(HITP)₂, a carbon nanowire, a carbon nanotube, a carbon nanorod, 1D metal, intercalated 1D metal, N-doped 1D metal, O-doped 1D metal, modified 1D metal, 1D alloy, intercalated 1D alloy, N-doped 1D alloy, O-doped 1D alloy, modified 1D alloy, 2D metal, intercalated 2D metal, N-doped 2D metal, O-doped 2D metal, modified 2D metal, 2D alloy, intercalated 2D alloy, N-doped 2D alloy, O-doped 2D alloy, modified 2D alloy, or combinations thereof.

4. The method of claim 1, wherein the second portion of the etch stop layer is treated in the patterning process.

5. The method of claim 1, wherein the second portion of the etch stop layer is treated by a dry etching process.

6. The method of claim 1, wherein:
each of the first portion and the second portion of the etch stop layer includes a metal material;
before treating the second portion of the etch stop layer, a concentration of non-metal elements in the second portion is same as a concentration of the non-metal elements in the first portion; and
after treating the second portion of the etch stop layer, a concentration of the non-metal elements in the second portion is greater than a concentration of the non-metal elements in the first portion.

7. The method of claim 6, wherein the metal material includes titanium, tantalum, or a combination thereof, and the non-metal elements include oxygen elements, nitrogen elements, or a combination thereof.

8. The method of claim 1, wherein:
before treating the second portion of the etch stop layer, the first portion and the second portion of the etch stop layer have a same material that is a metal material; and
in treating the second portion of the etch stop layer, non-metal elements are diffused into the metal material in the second portion.

9. The method of claim 8, wherein a concentration of the non-metal elements in a lower part of the second portion of the etch stop layer that is proximate to the lower interconnect layer is no greater than a concentration of the non-metal elements in an upper part of the second portion that is distal from the lower interconnect layer.

10. The method of claim 1, wherein the upper dielectric feature includes a barrier layer and an inner dielectric layer that is separated from the upper conductive feature by the barrier layer.

11. The method of claim 10, wherein the barrier layer includes aluminum nitride, aluminum oxide, silicon oxide, silicon oxycarbide, silicon oxycarbonitride, or combinations thereof.

12. The method of claim 10, wherein the dielectric layer includes silicon oxide, silicon oxycarbide, silicon oxycarbonitride, or combinations thereof, and has a dielectric constant ranging from 1.5 to 3.9.

13. The method of claim 10, wherein a dielectric constant of the barrier layer is greater than a dielectric constant of the inner dielectric layer.

14. The method of claim 10, wherein an electrical conductivity of the first portion of the etch stop layer is greater than an electrical conductivity of the barrier layer.

15. The method of claim 10, wherein the upper dielectric feature is formed with an air gap located between the barrier layer and the inner dielectric layer.

16. The method of claim 1, wherein:
after treating the second portion of the etch stop layer, the second portion is removed; and
after removing the second portion, the upper dielectric feature is formed in the trench.

17. A method for manufacturing an interconnect structure, comprising:
forming a lower interconnect layer over a base structure that is formed with at least one transistor, the lower interconnect layer including a lower conductive feature and a lower dielectric feature, the lower conductive feature being made of a first conductive material;
forming an etch stop layer on the lower interconnect layer, the etch stop layer being made of a metal material different from the first conductive material;
forming an upper conductive feature on the etch stop layer, the upper conductive feature being thicker than the lower conductive feature, the upper conductive feature being made of a second conductive material different from the metal material;
performing a patterning process to pattern the upper conductive feature and the etch stop layer so as to form a trench; and
forming an upper dielectric feature in the trench.

18. The method of claim 15, wherein the etch stop layer includes titanium, tantalum, alloys thereof, or combinations thereof.

19. The method of claim 17, wherein the upper dielectric feature includes a barrier layer and an inner dielectric layer that is separated from the upper conductive feature by the barrier layer, an electrical conductivity of the etch stop layer is greater than an electrical conductivity of the barrier layer.

20. An interconnect structure, comprising:
a lower interconnect layer formed over a base structure including at least one transistor, the lower interconnect layer including a lower dielectric feature and a lower conductive feature;
an upper interconnect layer formed on the lower interconnect layer opposite to the base structure, the upper interconnect layer including an upper conductive feature and an upper dielectric feature, a thickness of the upper conductive feature being greater than a thickness of the lower conductive feature; and
an etch stop layer disposed between the lower interconnect layer and the upper interconnect layer, and having a first portion and a second portion, the first portion being disposed between the upper conductive feature and the lower conductive feature, the second portion being disposed between the upper dielectric feature and the lower dielectric feature, an electrical resistance of the first portion being less than an electrical resistance of the second portion.
